(19) United States
(12) Patent Application Publication
(10) Pub. No.: US 2023/0268721 A1
(43) Pub. Date: Aug. 24, 2023

(54) Long-Wavelength Interband Cascade Lasers (ICLs) and Methods of Use

(71) Applicants: The Board of Regents of the University of Oklahoma, Norman, OK (US); Sandia National Laboratories, Albuquerque, NM (US)

(72) Inventors: Rui Q. Yang, Norman, OK (US); John F. Klem, Albuquerque, NM (US)

(21) Appl. No.: 18/168,337

(22) Filed: Feb. 13, 2023

Related U.S. Application Data
(60) Provisional application No. 63/312,238, filed on Feb. 21, 2022.

(51) Int. Cl. H01S 5/34; H01S 5/343

(52) U.S. Cl. CPC H01S 5/3402; H01S 5/34306; H01S 5/3422

(57) ABSTRACT

An ICL comprises: a plurality of IC stages, wherein each of the IC stages comprises: a hole injector; an electron injector; an active region coupled to the hole injector and the electron injector and comprising a first layer, wherein the first layer comprises a first material, and wherein the first material comprises InAsP or AlInAsP; a conduction band running through the hole injector, the electron injector, and the active region; and a valence band running through the hole injector, the electron injector, and the active region.

### CROSS-REFERENCE TO RELATED APPLICATIONS

This claims priority to U.S. Prov. Patent App. No. 63/312,238 filed on Feb. 21, 2022, which is incorporated by reference.

### STATEMENT REGARDING FEDERALLY SPONSORED RESEARCH OR DEVELOPMENT

This invention was made with government support under Contract Number 1931193 awarded by the National Science Foundation (NSF) and under Contract Number DE-NA0003525 awarded by the U.S. Department of Energy/National Nuclear Security Administration. The government has certain rights in the invention.

### BACKGROUND

In the decades since the original proposal of the ICL, a multitude of developments have paved the way for this III-V based technology to yield efficient and coherent mid-IR sources. Operating in a wide range of wavelengths from below 3 μm to above 11 μm, ICLs based on the type-II QW active region boast many technological applications including gas/chemical sensing, imaging, and industrial process control.

While type-II ICLs, grown mostly on GaSb substrates, have demonstrated efficient room temperature operation in the 3-6 μm range, two key questions remain: 1) Can the ICL support longer wavelength operation with low threshold current densities? and 2) Just how far into the longer-wavelength regime can the ICL technology be pushed? It should be noted that extension to longer wavelengths is challenging for the mature GaSb-based ICLs. This is primarily due to the InAs/AlSb SL needed to form the optical cladding layers. Such an SL would need to be significantly thicker to accommodate the longer optical wave decay length, which complicates the MBE growth. Additionally, the SL has a low thermal conductivity, so an increase in the overall SL thickness would cause the thermal resistance of the device to increase accordingly, hindering performance.

One solution to alleviate such concerns is to instead grow ICL structures on InAs substrates and replace the InAs/AlSb SL cladding with n⁺-doped InAs plasmon-enhanced cladding in combination with undoped InAs SCLs. This InAs-based approach enabled pulsed lasing up to 55° C. near 7.1 μm and extended the ICL operation to 11.1 μm, the longest wavelength at the time among III-V interband lasers. However, the Jₜₕ of the latter, long-wavelength device was relatively high (e.g., 95 A/cm² at 80 K in CW mode near 10.8 μm) and operated only up to 97 and 130 K in CW and pulsed modes, respectively. This relatively modest device performance can be improved significantly by using an advanced waveguide configuration, which was later developed for InAs-based ICLs operating near 4.6 μm. By introducing an intermediate SL cladding layer between the SCL and the plasmon cladding layer, the advanced waveguide configuration can enhance the optical confinement and simultaneously reduce the optical loss, resulting in a low Jₜₕ. Although plasmon-enhanced waveguide ICLs can be achieved on GaSb substrates with heavily doped n⁺-InAsSb layers and GaSb SCLs, this occurs at the cost of more complicated carrier transport and MBE growth.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 shows a band-edge diagram of one cascade stage and the layer sequence for the 7342 wafer.

FIG. 2 shows Jₜₕ as a function of T for several devices made from the 7289 wafer. The inset depicts the pulsed lasing spectrum for device EB7289BA1-1A at various temperatures.

FIG. 3 shows Jₜₕ as a function of T for several devices from the 7342 wafer. The right inset shows the pulsed lasing spectrum for device EB7342BA1-3E with the 7342 wafer, while the left inset shows a zoomed-in view depicting the blue shift of 4 nm.

FIG. 4 shows the current-voltage and current-output power characteristics for device EB7289BA1-1A with the 7289 wafer in CW mode, where arrows indicate threshold at various temperatures. The inset shows the CW emission spectra between 80 K and 107 K.

FIG. 5 shows the pulsed output power as a function of injection current at several temperatures for device EB7289BA1-1A with the 7289 wafer.

FIG. 6 shows pulsed current-voltage and current-output power characteristics at several temperatures for device EB7342BA1-3F with the 7342 wafer. The inset is its lasing spectrum at 120 K.

FIG. 7 is a band edge diagram for one cascade period of EB7541/EB7547, which does not include InA_{0.5}P_{0.5} barriers in the QW active region.

FIG. 8 is a band edge diagram for one cascade period of EB7523/EB7539, which includes InA_{0.5}P_{0.5} barriers in the QW active region.

FIG. 9 is a graph showing a calculated optical modal profile and refractive index of the waveguide for EB7541 at 80 K with an emission wavelength λ measured from the pulsed spectra of 10.2 μm.

FIG. 10 is a graph showing a measured XRD spectrum (top) compared to the simulated spectrum (bottom) for ICL wafer EB7541.

FIG. 11 is a graph showing Jₜₕ as a function of temperature for several devices made from four InAs-based ICL wafers.

FIG. 12A is a graph showing CW results for the IVL characteristics for EB7541BA3-3H.

FIG. 12B is a graph showing CW emission spectrum for EB7541BA3-3H between 80 K and 123 K.

FIG. 13 is a graph showing pulsed IVL characteristics for EB7541BA3-3H with the lasing spectrum (inset) at 150 and 155 K.

FIG. 14 is a graph showing IVL characteristics for EB7547BA3-2A in CW mode. The inset shows the CW lasing spectrum between 80 K and 102 K.

FIG. 15 is a graph showing pulsed IVL characteristics for EB7547BA3-2A with the lasing spectrum (inset) at 120 and 137 K.

FIG. 16 is a graph showing IVL characteristics for EB7523BA3-2F in CW mode. The inset shows the CW emission spectrum between 80 K and 90 K.

FIG. 17A is a graph showing pulsed results for the IVL characteristics for EB7523BA3-2F.

FIG. 17B is a graph showing pulsed emission spectrum for EB7523BA3-2F between 80 K and 160 K.

FIG. 18 is a graph showing IVL characteristics for EB7539BA2-2D in CW mode. The inset shows the CW emission spectrum between 80 K and 85 K.

FIG. 19 is a graph showing IVL, characteristics for EB7539BA2-2A in pulsed mode. The inset shows the pulsed emission spectrum between 120 K and 150 K.

### DETAILED DESCRIPTION

Disclosed herein are InAs-based ICLs with an advanced waveguide structure having improved device performance in terms of reduced threshold current densities for ICLs near 11 μm in a 7289 wafer, or extended operating wavelength beyond 13 μm in a 7342 wafer. In the 7289 wafer, ICLs near 11 μm yielded a significantly reduced CW lasing threshold of 23 A/cm² at 80 K with substantially increased CW output power compared with previous ICLs at similar wavelengths. In the 7342 wafer, ICLs incorporated an innovative QW active region, comprised of InAsP layers, and lased in pulsed mode up to 120 K at 13.2 μm, the longest wavelength yet achieved for III-V interband lasers.

Before further describing various embodiments of the apparatus, component parts, and methods of the present disclosure in more detail by way of exemplary description, examples, and results, it is to be understood that the embodiments of the present disclosure are not limited in application to the details of apparatus, component parts, and methods as set forth in the following description. The embodiments of the apparatus, component parts, and methods of the present disclosure are capable of being practiced or carried out in various ways not explicitly described herein. As such, the language used herein is intended to be given the broadest possible scope and meaning; and the embodiments are meant to be exemplary, not exhaustive. Also, it is to be understood that the phraseology and terminology employed herein is for the purpose of description and should not be regarded as limiting unless otherwise indicated as so. Moreover, in the following detailed description, numerous specific details are set forth in order to provide a more thorough understanding of the disclosure. However, it will be apparent to a person having ordinary skill in the art that the embodiments of the present disclosure may be practiced without these specific details. In other instances, features which are well known to persons of ordinary skill in the art have not been described in detail to avoid unnecessary complication of the description. While the apparatus, component parts, and methods of the present disclosure have been described in terms of particular embodiments, it will be apparent to those of skill in the art that variations may be applied to the apparatus, component parts, and/or methods and in the steps or in the sequence of steps of the method described herein without departing from the concept, spirit, and scope of the inventive concepts as described herein. All such similar substitutes and modifications apparent to those having ordinary skill in the art are deemed to be within the spirit and scope of the inventive concepts as disclosed herein.

All patents, published patent applications, and non-patent publications referenced or mentioned in any portion of the present specification are indicative of the level of skill of those skilled in the art to which the present disclosure pertains, and are hereby expressly incorporated by reference in their entirety to the same extent as if the contents of each individual patent or publication was specifically and individually incorporated herein.

Unless otherwise defined herein, scientific and technical terms used in connection with the present disclosure shall have the meanings that are commonly understood by those having ordinary skill in the art. Further, unless otherwise required by context, singular terms shall include pluralities and plural terms shall include the singular.

As utilized in accordance with the methods and compositions of the present disclosure, the following terms and phrases, unless otherwise indicated, shall be understood to have the following meanings: The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or when the alternatives are mutually exclusive, although the disclosure supports a definition that refers to only alternatives and “and/or.” The use of the term “at least one” will be understood to include one as well as any quantity more than one, including but not limited to, 2, 3, 4, 5, 6, 7, 8, 9, 10, 15, 20, 30, 40, 50, 100, or any integer inclusive therein. The phrase “at least one” may extend up to 100 or 1000 or more, depending on the term to which it is attached; in addition, the quantities of 100/1000 are not to be considered limiting, as higher limits may also produce satisfactory results. In addition, the use of the term “at least one of X, Y and Z” will be understood to include X alone, Y alone, and Z alone, as well as any combination of X, Y and Z.

As used in this specification and claims, the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AAB, BBC, AAABCCCC, CBBAAA, CABABB, and so forth. The skilled artisan will understand that typically there is no limit on the number of items or terms in any combination, unless otherwise apparent from the context.

Throughout this application, the terms “about” or “approximately” are used to indicate that a value includes the inherent variation of error for the apparatus, composition, or the methods or the variation that exists among the objects, or study subjects. As used herein the qualifiers “about” or “approximately” are intended to include not only the exact value, amount, degree, orientation, or other qualified characteristic or value, but are intended to include some slight variations due to measuring error, manufacturing tolerances, stress exerted on various parts or components, observer error, wear and tear, and combinations thereof, for example. The terms “about” or “approximately”, where used herein when referring to a measurable value such as an amount, percentage, temporal duration, and the like, is meant to encompass, for example, variations of ±20% or ±10%, or ±5%, or ±1%, or ±0.1% from the specified value, as such variations are appropriate to perform the disclosed methods and as understood by persons having ordinary skill in the art. As used herein, the term “substantially” means that the subsequently described event or circumstance completely occurs or that the subsequently described event or circumstance occurs to a great extent or degree. For example, the term “substantially” means that the subsequently described event or circumstance occurs at least 90% of the time, or at least 95% of the time, or at least 98% of the time.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

As used herein, all numerical values or ranges include fractions of the values and integers within such ranges and fractions of the integers within such ranges unless the context clearly indicates otherwise. Thus, to illustrate, reference to a numerical range, such as 1-10 includes 1, 2, 3, 4, 5, 6, 7, 8, 9, 10, as well as 1.1, 1.2, 1.3, 1.4, 1.5, etc., and so forth. Reference to a range of 1-50 therefore includes 1, 2, 3, 4, 5, 6, 7, 8, 9, 10, 11, 12, 13, 14, 15, 16, 17, 18, 19, 20, etc., up to and including 50, as well as 1.1, 1.2, 1.3, 1.4, 1.5, etc., 2.1, 2.2, 2.3, 2.4, 2.5, etc., and so forth. Reference to a series of ranges includes ranges which combine the values of the boundaries of different ranges within the series. Thus, to illustrate reference to a series of ranges, for example, a range of 1-1,000 includes, for example, 1-10, 10-20, 20-30, 30-40, 40-50, 50-60, 60-75, 75-100, 100-150, 150-200, 200-250, 250-300, 300-400, 400-500, 500-750, 750-1,000, and includes ranges of 1-20, 10-50, 50-100, 100-500, and 500-1,000. The range 100 units to 2000 units therefore refers to and includes all values or ranges of values of the units, and fractions of the values of the units and integers within said range, including for example, but not limited to 100 units to 1000 units, 100 units to 500 units, 200 units to 1000 units, 300 units to 1500 units, 400 units to 2000 units, 500 units to 2000 units, 500 units to 1000 units, 250 units to 1750 units, 250 units to 1200 units, 750 units to 2000 units, 150 units to 1500 units, 100 units to 1250 units, and 800 units to 1200 units. Any two values within the range of about 100 units to about 2000 units therefore can be used to set the lower and upper boundaries of a range in accordance with the embodiments of the present disclosure. More particularly, a range of 10-12 units includes, for example, 10, 10.1, 10.2, 10.3, 10.4, 10.5, 10.6, 10.7, 10.8, 10.9, 11.0, 11.1, 11.2, 11.3, 11.4, 11.5, 11.6, 11.7, 11.8, 11.9, and 12.0, and all values or ranges of values of the units, and fractions of the values of the units and integers within said range, and ranges which combine the values of the boundaries of different ranges within the series, e.g., 10.1 to 11.5.

The present disclosure will now be discussed in terms of several specific, non-limiting, examples and embodiments. The examples described below, which include particular embodiments, will serve to illustrate the practice of the present disclosure, it being understood that the particulars shown are by way of example and for purposes of illustrative discussion of particular embodiments and are presented in the cause of providing what is believed to be a useful and readily understood description of procedures as well as of the principles and conceptual aspects of the present disclosure.

The following abbreviations apply:
A: ampere(s)
A: angstrom(s)
AlGaInAsN: aluminum gallium indium arsenic nitride
AlGaInAsP: aluminum gallium indium arsenic phosphide
AlInAsP: aluminum indium arsenic phosphide
AlSb: aluminum antimonide
AlSbAs: aluminum antimony arsenide
BA: broad area
cm²: centimeter(s) square
cm⁻¹: inverse centimeter(s)
cm⁻²: inverse centimeter(s) square
CW: continuous wave
DIC: differential interference contrast
EQE: external quantum efficiency
FTIR: Fourier transform infrared spectrometer
GaInAsN: gallium indium arsenic nitride
GaInSb: gallium indium antimonide
GaSb: gallium antimonide
Gₜₕ: threshold gain
hr: hour(s)
I: injection current
ICL: interband cascade laser
InAs: indium arsenide
InAsP: indium arsenic phosphide
InAsSb: indium arsenic antimonide
IQE: internal quantum efficiency
IR: infrared
IVL: current-voltage-power
Jₜₕ: threshold current density
K: Kelvin
kHz: kilohertz
LW: long-wave
mA: milliampere(s)
MBE: molecular beam epitaxy
mm: millimeter(s)
mW: milliwatt(s)
Nc: number of cascade stages
n_{eff}: effective refractive index of the entire waveguide
nm: nanometer(s)
NSF: National Science Foundation
QW: quantum well
SCL: separate confinement layer
SL: superlattice
SRH: Shockley-Read-Hall
T: temperature
UV: ultraviolet
V: volt(s)
Vₜₕ: threshold voltage
XRD: x-ray diffraction
αᵢ: internal loss
αₘ: mirror loss
α_{wg}: waveguide loss
Γ: optical confinement factor
μm: micrometer(s)
7289: reference first embodiment ICL
7342: disclosed second embodiment ICL
° C.: degree(s) Celsius.

7289 and 7342 Wafers

Returning to the description of the various embodiments of the disclosure, herein are disclosed InAs-based ICLs with the advanced waveguide structure for long wavelength operation. Devices with a 7289 wafer showed significantly reduced threshold current densities compared to previous ICLs at similar wavelengths near 11 μm. Devices with a 7342 wafer extended the lasing wavelength of ICLs longer than 13 μm with an innovative QW active region comprised of InAsP layers based on the relevant perspective on band-edge positions in type-II heterostructures, which discussed a method to address the issue of a reduced wavefunction overlap for photon emission at long wavelengths with spatially indirect transitions in a type-II QW.

Two sets of 20-stage ICLs were grown on InAs substrates, both including the advanced waveguide design, where the layer thicknesses of the intermediate SL cladding and InAs SCL layers were 1.65 μm and 0.83 μm, respectively. The bottom n⁺-InAs plasmon cladding layer thickness was 2 μm, while the top was 1.1 μm. The doping level of the plasmon cladding was 3.2×10¹⁸ cm⁻², which was lowered by approximately 54% compared with Lu Li, et al., “MBE-grown long-wavelength interband cascade lasers on InAs substrates,” Journal of Crystal Growth, 425, 369 (2015), which is incorporated by reference, to reduce optical losses due to free carrier absorption.

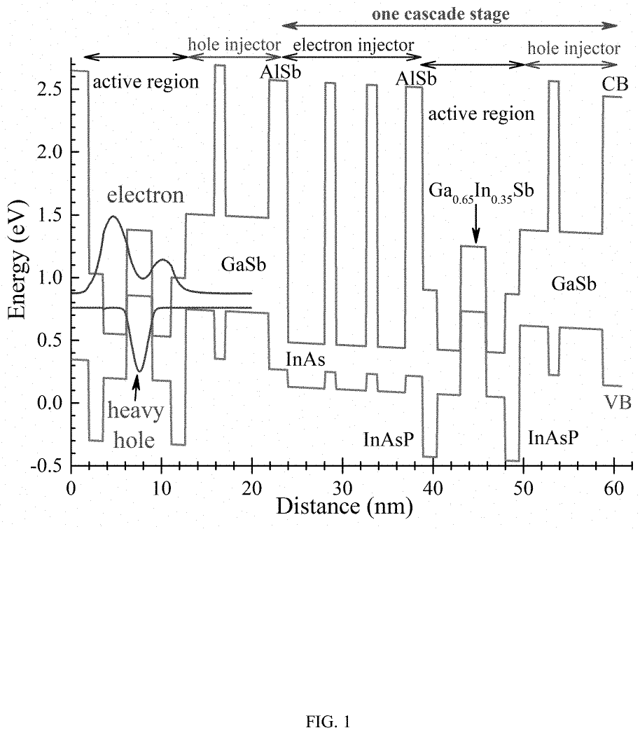

In addition to adapting the advanced waveguide for both ICLs, the 7342 wafer had a modified active region compared with the 7289 wafer in order to enhance its long wavelength operation. In the 7289 wafer, a typical AlSbAs/InAs/Ga_{0.65}In_{0.35}Sb/InAs/AlSbAs W-shape QW active region was employed with layer thicknesses of 23/34.5/28/31.5/12 Å in the growth direction. When extending operation to longer wavelengths, a thicker InAs layer may be needed, which leads to a reduced electron-hole wavefunction overlap in this type-II QW as the electrons and holes are mainly localized at different layers. This could cause the optical gain (generated from the spatially indirect interband transition in the type-II QW) to be insufficient to overcome the increased loss at a long wavelength and thus render the lasing unreachable. But as pointed out in R. Q. Yang, “Electronic States and Interband Tunneling Conditions in Type-II Quantum Well Heterostructures,” J. Appl. Phys. 127, 025705 (2020), which is incorporated by reference, the energy level of an electronic state in a QW could be moved down by using a barrier layer with a low valence band-edge, resulting in a lower interband transition energy for photon emission at longer wavelengths. Phosphorus-containing compounds are such a barrier material that can lower the electron energy level for longer wavelength emission without increasing the InAs layer thickness. So, for the 7342 wafer, a modified active region consisting of a AlSbAs/InAs_{0.5}P_{0.5}/InAs/Ga_{0.65}In_{0.35}Sb/InAs/InAs_{0.5}P_{0.5} QW was grown, with layer thicknesses of 19/16/26.5/28/21.5/16 Å, respectively, where the InAs layer thicknesses were substantially reduced (e.g., 26.5 vs. 34.5 A) compared to that in the first ICL wafer. The band-edge diagram of one cascade stage along with the layer sequence for the 2nd ICL wafer is given in FIG. 1, which is a qualitative illustration rather than an exact description considering that there exist some uncertainties and variations in material parameters due to several factors such as interfacial compositions and strains. As shown in FIG. 1, in each cascade stage, the QW active region is sandwiched by the electron injector and hole injector, which are composed of InAs/AlSb(As) and GaSb/AlSb(As) multiple QWs, respectively.

FIG. 1 shows InAsP in the active region. However, other InAsP-based materials such as AlGaInAsP and AlInAsP are possible. In addition, other non-InAsP-based materials such as AlGaInAsN are also possible. Additional layers may be between the InAsP layers and comprise different materials such as GaInAsN.

The grown wafers were fabricated into 100-μm-wide (EB7289BA1-1A and EB7342BA1-3G devices) and 150-μm-wide (EB7289BA1-1E, EB7342BA1-3F, and EB7342BA1-3E devices) BA mesas using wet chemical etching. The wafers were left un-thinned and cleaved into 1.5-mm-long laser bars without facet coating, which were mounted epi-side up on copper heat sinks for testing.

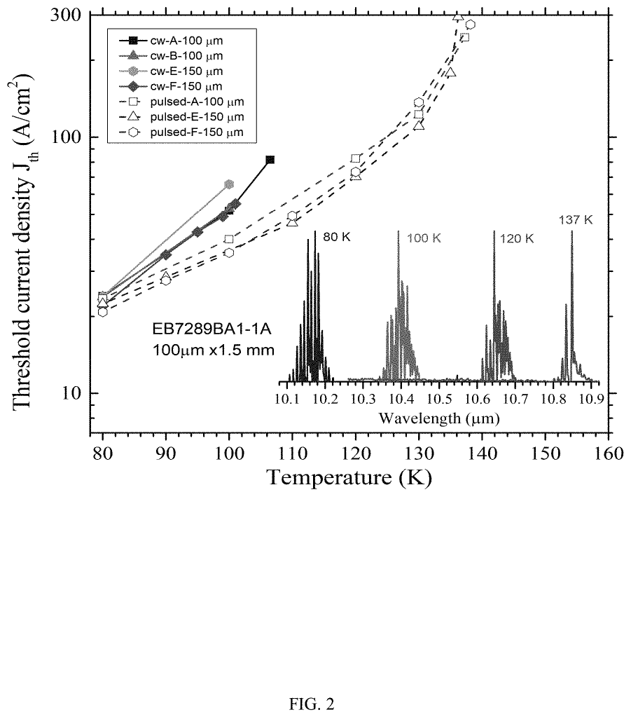

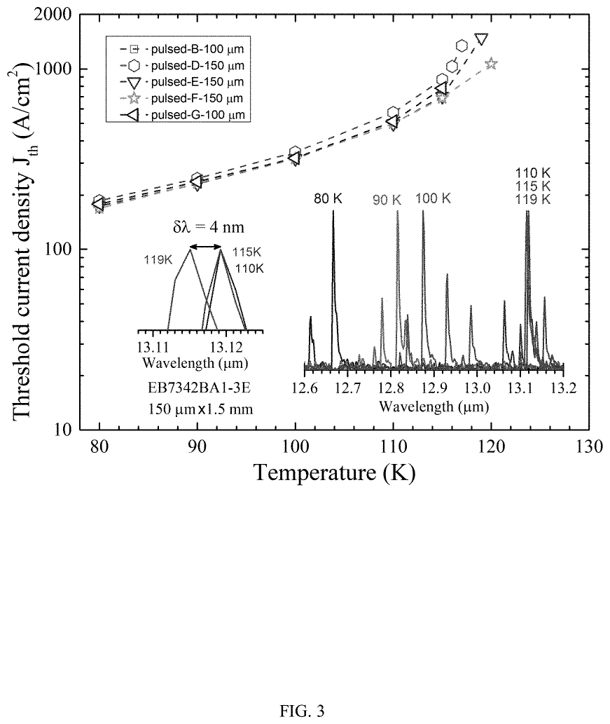

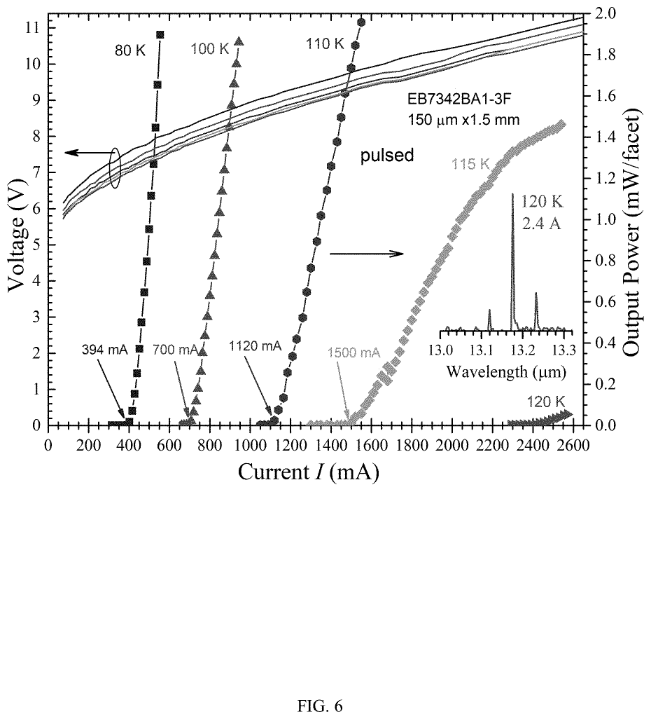

Multiple EB7289 devices were able to operate in CW mode above 100 K, and in pulsed mode above 130 K with lasing wavelengths near 11 μm, as shown in FIG. 2. The EB7342 devices were only able to operate in pulsed mode (1 μs pulse width and 5 kHz repetition rate) at temperatures up to 120 K at wavelengths beyond 13 μm as shown in FIG. 3 (and the inset in FIG. 6), which is the longest ever reported among III-V interband lasers. This verified the theoretical prediction that P-containing barrier layers could lower the electronic energy level in a QW with reduced InAs layer thicknesses.

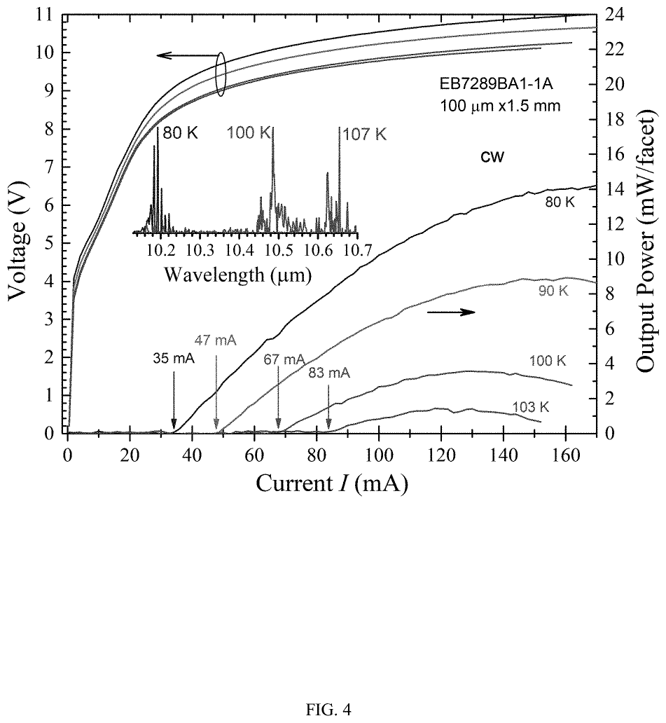

In CW mode, a representative device from the first ICL wafer, EB7289BA1-1A, lased at 10.2 μm at 80 K and operated up to 107 K at an emission wavelength of 10.65 μm as shown in the inset in FIG. 4. At 80 K, Jₜₕ was ˜23 A/cm², which is a reduction of about four times compared with the previously reported 20-stage ICL with a similar wavelength described in one approach, but 2.3 times that of a 15-stage ICL emitting at 9 μm at 80 K in another approach. Vₜₕ of this device was 9.2 V at 80 K, which is significantly higher than the typical value (3.9 V) of previous 20-stage ICLs. The high Vₜₕ and the corresponding possible issue in carrier transport limited the maximum CW and pulsed operating temperatures, which is reflected by the maximum allowable threshold current density (82 A/cm² in CW and <300 A/cm² in pulsed mode) as shown in FIG. 2. The CW output power for this device was 14.3 mW/facet with an injection current of 172 mA at 80 K, which is an increase of approximately four times compared with that for the ICL in one approach and comparable to that (15 mW for the 9 μm ICL at 200 mA) discussed in another approach. Appreciable output power was obtained at temperatures up to 103 K as shown in FIG. 4. Actual output power should be somewhat higher because the measurement does not account for beam divergence loss. Several EB7289 devices exhibited similar output powers. The increase in output power from these devices clearly indicates that the optical internal loss is reduced in the advanced waveguide configuration compared to previous ICLs with only plasmon cladding layers.

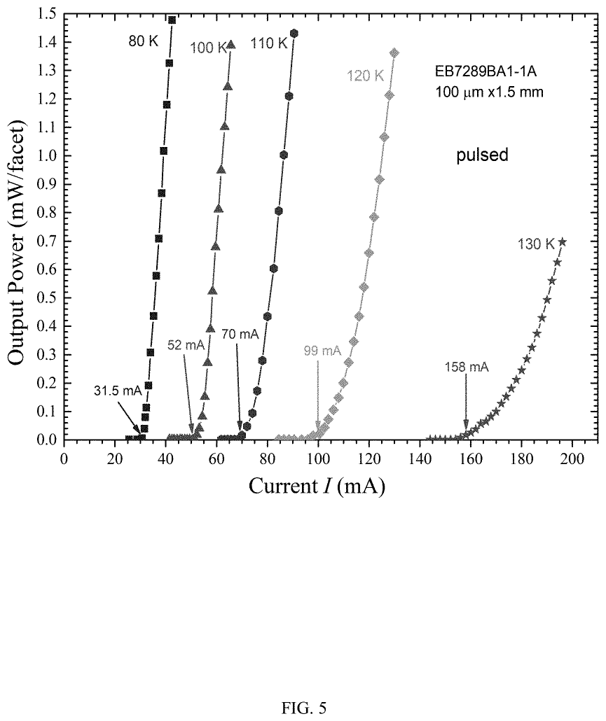

Under pulsed operation, EB7289BA1-1A was able to operate up to 137 K at a wavelength of 10.85 μm, as shown in the inset in FIG. 2, a slightly higher temperature than that in one approach, with a Jₜₕ of 245 A/cm². As shown in FIG. 5, the slope efficiency was nearly insensitive to temperature from 80 to 110 K. The extracted EQE reached ˜290% at 80 K, indicating the cascaded emission of photons in the ICL, and dropped to ˜60% at 130 K. According to the optical properties and threshold current densities, this laser should be capable of operating well above 130 K.

A representative device with the 7342 wafer, EB7342BA1-3G, lased at a wavelength of 12.7 μm in pulsed mode at 80 K, albeit with a large Jₜₕ of 179 A/cm². The maximum operating temperature for this device was 115 K, at a lasing wavelength of 13.23 μm, which represents a new record for long wavelength operation among III-V interband lasers. Also, three more devices with the 7342 wafer, EB7342BA1-3E, EB7342BA1-3D and EB7342BA1-3F, were able to lase at slightly higher temperatures of 119, 117, and 120 K, respectively. However, the lasing wavelength for device EB7342BA1-3E at 119 K was shorter, at 13.11 μm (similarly for device EB7342BA1-3D). This is due to the band filling effect, as shown in the insets in FIG. 3 (for device EB7342BA1-3E), which can occur in mid-IR lasers and placed an upper wavelength limit of 9.5 μm for optically pumped Sb-based type-II QW lasers. The effect occurs because, as the lasing emission is pushed toward longer wavelengths with increasing temperature, the waveguide loss rapidly increases and there also tends to be a reduced modal overlap with the gain medium. Taken together, these effects cause an increase in threshold current density and the number of carriers at higher energy states, which shifts the peak optical gain to a higher energy, resulting in the blue shift of lasing wavelength rather than a red shift with narrowing bandgap when temperature is increased. This blue-shift effect is also a limiting factor for the longer wavelength operation because one cannot simply increase optical gain to reach the threshold with a high current injection. The observed blue-shift for device EB7342BA1-3E from 115 to 119 K is approximately 4 nm, as indicated in the inset of FIG. 3.

Compared with devices with the 7289 wafer, those with the 7342 wafer consistently lased with significantly higher threshold current densities, and only in pulsed-mode operation, though they have the same waveguide structure with identical doping profile. The threshold voltage for devices made from the second ICL wafer was ˜7.5 V at 80 K and increased at higher temperatures due to the rapid increase of threshold current as shown in FIG. 6, which is also higher than what is typically expected and implies similar issues as in devices with the 7289 wafer. Nevertheless, devices with the 7342 wafer sustain lasing at higher threshold current densities (>1000 A/cm²) as shown in FIG. 3. This indicates that possible issues related to carrier transport might be less severe in the 7342 wafer, which is also reflected by a lower voltage (˜6 V) at 75 mA as shown in FIG. 6 compared to that (>9 V in FIG. 4) in devices with the 7289 wafer. Considering that the transparency carrier density is usually low at low temperatures and devices with the 7342 wafer lased at substantially longer wavelengths with a modified active QW region, the higher threshold current density may be mainly related to high optical internal loss due to more free-carrier absorption and other mechanisms such as inter-subband transitions in QWs. To examine this, the peak output power as a function of I for device EB7342BA1-3F was measured and shown in FIG. 6. The extracted EQE was 41% at 80 K, 18% at 100 K, 12% at 110 K, 5.3% at 115 K, and 0.67% at 120K, which are much lower than that obtained from device EB7289BA1-1A. This indicates that high internal absorption loss is a major cause for the higher threshold current density in devices made with the 7342 wafer. Nevertheless, the innovative QW active region produced a sufficient gain at a moderate threshold current density to overcome the increased absorption loss at such a long wavelength.

InAs-based ICLs having improved device performance at emission wavelengths near 11 μm have been disclosed. Furthermore, a modified QW active region has been implemented into an ICL structure and has enabled ICL operation beyond 13 μm, which confirmed a theoretical prediction and paved the way to further exploration of ICLs in the long-wavelength region. For a wide range of practical applications, these long-wavelength ICLs need to be capable of operating at room temperature.

7541, 7547, 7523, and 7539 Wafers

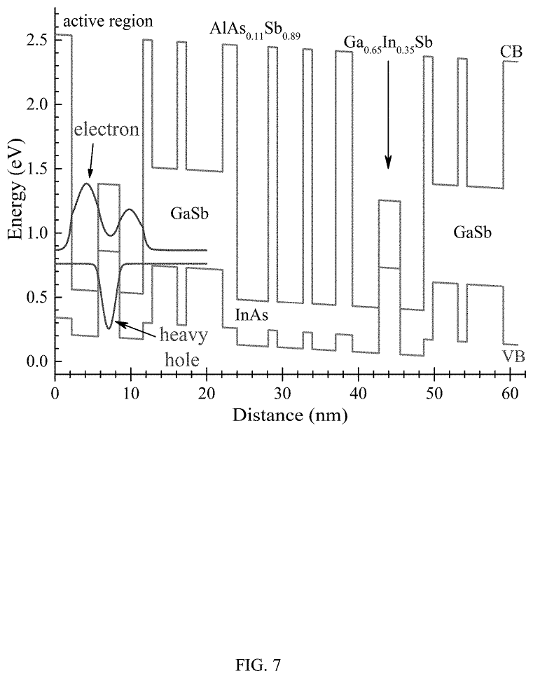

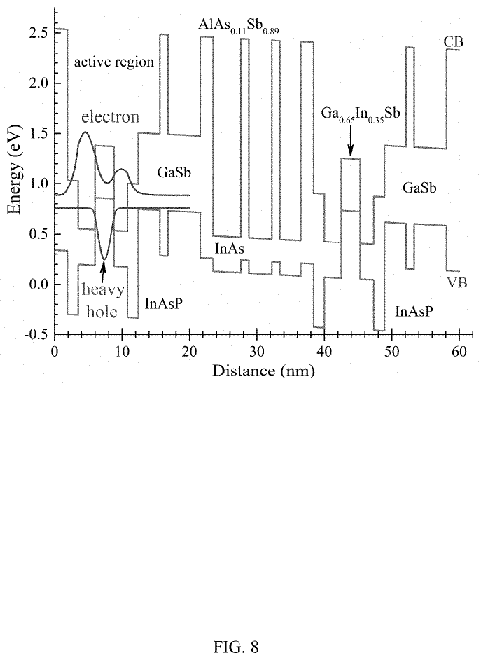

Four ICL wafers, EB7541, EB7547, EB7523, and EB7539, were grown by MBE on InAs substrates, all of which incorporated the advanced waveguide, and two of which, EB7523 and EB7539, included the InA_{0.5}P_{0.5} barriers in the QW active region. For EB7541 (EB7547), a regular W-QW structure was used, consisting of a layer sequence of AlAs_{0.89}Sb_{0.11}/InAs/Ga_{0.65}In_{0.35}Sb/InAs/AlAs_{0.89}Sb_{0.11}, with thicknesses of 22/35(36.5)/28/31(31.5)/12 Å. For EB7523 (EB7539), the active region had a layer sequence of AlAs_{0.89}Sb_{0.11}/InA_{0.5}P_{0.5}/InAs/Ga_{0.65}In_{0.35}Sb/InAs/InA_{0.5}P_{0.5}, with thicknesses of 19/16/25(26)/28/20/16 Å in the growth direction. Here the InAs layer thicknesses in the latter wafers EB7523 and EB7539 were reduced by about 30% in the first InAs QW and about 35% in the second InAs QW compared to the devices made from wafers EB7541 and EB7547 which did not include InA_{0.5}P_{0.5} barriers. Based on a 2-band k·p model, the estimated wavefunction overlaps for EB7541 and EB7547 were 16.7% and 15.6%, respectively. The inclusion of the InA_{0.5}P_{0.5} barriers in the QW active region in EB7523 and EB7539 increased the estimated overlap to 19% and 18.2%, respectively. The band edge diagrams of one cascade stage for each of the two representative device structures (EB7541 and EB7523) are shown in FIGS. 7-8.

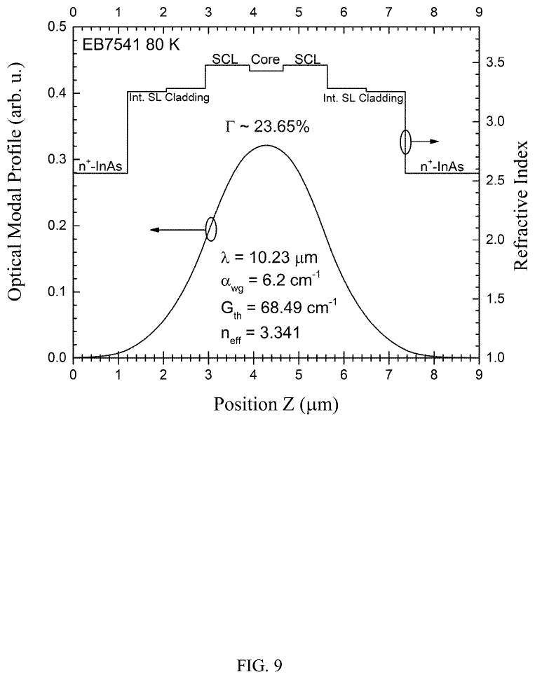

There were some uncertainties in the expected operating wavelength for InAs-based ICLs that incorporated the advanced waveguide and those that utilized the modified QW active region, which chiefly manifested in high internal absorption losses, leading to relatively large Jₜₕs, low EQEs, low output powers, and limited temperature performance. Therefore, several adjustments to the waveguide were made to reduce the internal loss and to better confine the optical wave within the QW active region. Since the expected emission for these ICLs was to be beyond 11 μm at higher operating temperatures, the waveguide layer thicknesses were slightly increased. Compared to the previous design, the thicknesses of the individual components were increased by about 18%, 5%, and 7% for the InAs SCL, InAs/AlSb SL intermediate cladding, and the ntInAs plasmon cladding layers, respectively. To further reduce losses due to free carrier absorption in the n⁺-InAs plasmon cladding, the doping concentration there was reduced by about 13%. Also, the doping in the injection region was reduced by about 31%. The calculated optical modal profile and refractive index based on a slab waveguide model for a representative device (EB7541) are shown in FIG. 9. In each of the SL intermediate cladding layers, to reduce the free-carrier absorption loss, there are two segments with different doping levels. The segment that is closer to the cascade region has lower doping, resulting in a slightly higher real part of its refractive index. FIG. 9 shows α_{wg}, Gₜₕ, n_{eff}, and Γ. In the simulation, the internal loss (waveguide loss) is calculated based only on free carrier absorption, which gives a lower bound estimate to the overall internal loss within the device. The emission wavelength λ of each device was measured at 80 K in pulsed mode operation, which prevented potential red shifts that could be caused by local heating, and used in the waveguide simulations. The various optical parameters based on the waveguide simulations of the other devices reported here are listed in the Table.

TABLE

| Device | InAsP Barriers-InAs | 80 K λ | | α_{wg} | Gₜₕ | |
|---|---|---|---|---|---|---|
| Name | QW thickness (Å) | (μm) | Γ (%) | (cm⁻¹) | (cm⁻¹) | n_{eff} |
| EB7541 | No-35/31 | 10.2 | 23.65 | 6.2 | 68.49 | 3.341 |
| EB7547 | No-36.5/31.5 | 10.9 | 23.33 | 7.3 | 74.15 | 3.324 |
| EB7523 | Yes-25/20 | 11.8 | 22.61 | 8.7 | 82.69 | 3.300 |
| EB7539 | Yes-26/20 | 12.1 | 22.39 | 9.3 | 86.19 | 3.292 |

Calculated optical parameters of the four 20-stage InAs-based ICLs with the 80 K emission wavelength λ measured from the pulsed spectra.

The ICL wafers were grown by molecular beam epitaxy using solid sources except for P, which was supplied by a cracking phosphine injector. All layers were grown at 440° C. Growth rates were approximately 1.0 μm/hr for InAs and InAsP and 0.49 μm/hr for AlAsSb, GalnSb, and GaSb. The intermediate cladding layers were nominally InAs/AlSb superlattices, but since the As source valve was left open during the cladding AlSb layer growth and the As source shutter does not fully block the As flux, layers nominally grown as AlSb contained substantial As, which was accounted for in separate lattice matching calibration growths. The As source valve was closed during critical portions of the active region growth.

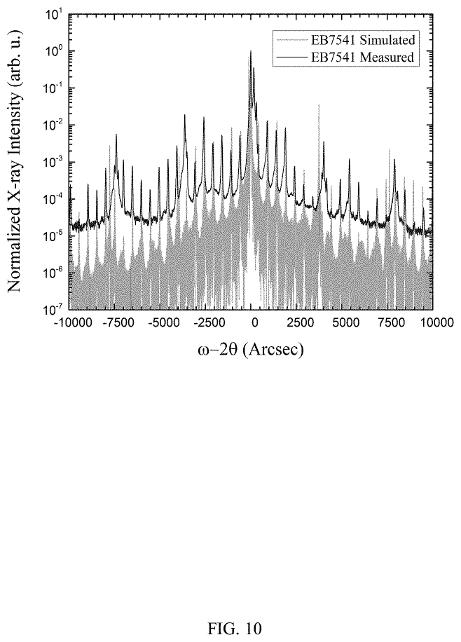

The material quality was analyzed using XRD, and the surface morphology was characterized by DIC microscopy. The XRD spectra were measured using a Panalytical X'Pert3 MRD. Symmetric scans along the (004) axis were obtained and show reasonable agreement with the simulated spectra, as shown in FIG. 10. From the XRD spectra, the InAs/AlSb SLs of all four ICL wafers show a slight compressive strain in the growth direction (biaxial tensile strain), with a substrate/SL zero-order peak separation ranging between 14-50 arcsec, corresponding to a lattice mismatch of 0.12-0.17%. The InAs/AlSb SL thickness across each of the four ICL wafers range from 0.12% thinner to 0.5% thicker, compared to the intended design. The cascade region was consistently thinner among all four wafers, ranging from 0.5%-1.3%, compared with the design.

The grown wafers were fabricated into 100-μm-wide (e.g. EB7523BA3-2F, EB7539BA2-2D, EB7541BA3-3H, and EB7547BA3-2A) and 150-μm-wide (e.g., EB7541BA3-1G, EB7547BA3-3C, EB7539BA2-2A) BA mesas using standard UV contact photolithography and wet chemical etching. The wafers were left unthinned and cleaved into approximately 1.5 mm-long laser bars without facet coating, which were mounted epi-side up on copper heat sinks for testing.

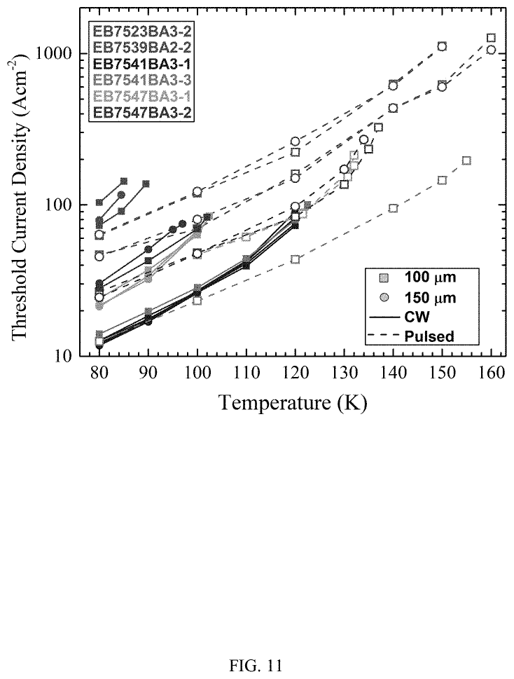

The fabricated devices were tested using a Nicolet FTIR, with CW power measurements carried out with a PM3 Coherent PowerMax thermopile power meter, in which the beam divergence loss was not included. Hence, the reported output power and EQE of the devices are conservative. Multiple devices from each of the four ICL wafers operated in both CW and pulsed modes, as shown in FIG. 11. All characteristics presented are from representative devices among the many tested. Of the four ICL wafers grown, EB7541 and EB7547 are most directly related for comparison purposes as they include only the advanced waveguide. EB7523 and EB7539 include both the advanced waveguide as well as the modified QW active region. ICLs made from them have significantly longer emission wavelengths than those of EB7541 and EB7547, and consequently their threshold current densities are larger as reflected in FIG. 11. Detailed characteristics of their device performance are discussed further below.

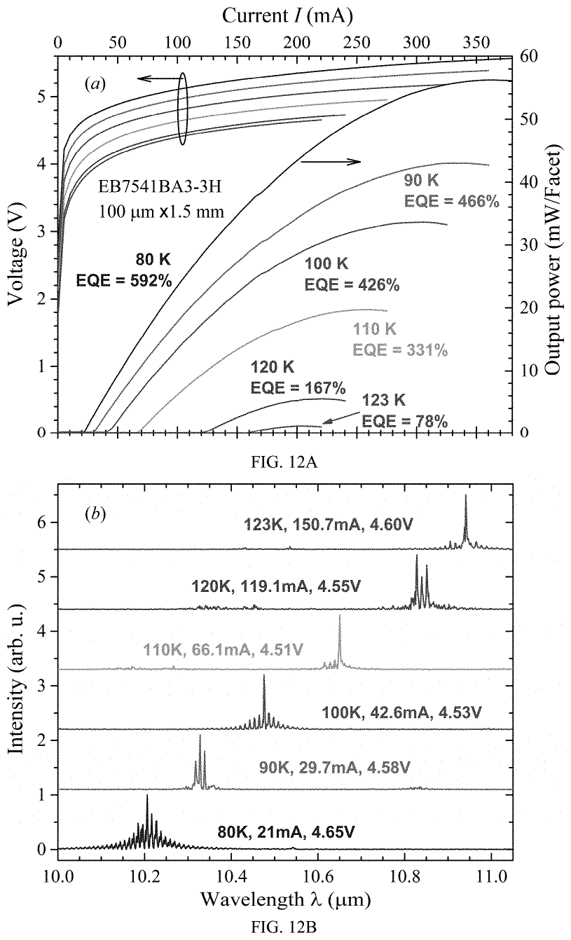

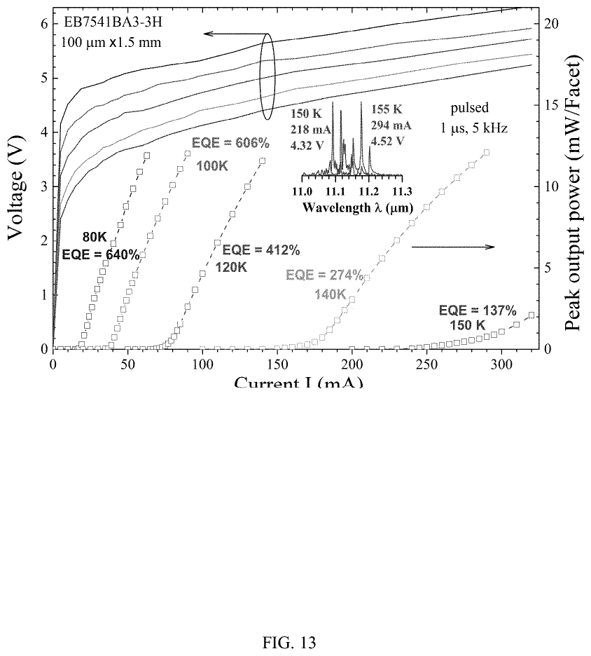

Wafers EB7541 and EB7547 both included the advanced waveguide, but did not include InA_{0.5}P_{0.5} barriers in the QW active region. In CW mode, two devices from EB7541 had threshold current densities as low as 12 A/cm² at 80 K, representing about a 50% reduction compared to previous ICLs operating at similar wavelengths. These ICLs lased at 10.2 μm at 80 K and then red shifted to longer wavelengths at high temperatures. The characteristics of a representative device, EB7541BA3-3H, are shown in FIGS. 12A and 12B. This device operated in CW mode up to 123 K, about 17 K higher than a previous ICL, with an emission wavelength of 10.9 μm and a Jₜₕ of about 101 A/cm². This device exhibited a significant increase in the measured CW output power at 80 K, just over 56 mW/facet, about four times as much as a previous ICL, as shown in FIG. 12A. The CW output power of 43 mW/facet at 200 mA is more than twice that (15 mW/facet) from an early ICL at the shorter lasing wavelength of 9.1 μm at 80 K and at the same current. Compared to other devices that have a Vₜₕ of about 9.2 V at 80 K, the CW threshold voltage was reduced by a factor of 2 (Vₜₕ of about 4.6 V at 80 K), resulting in a voltage efficiency of about 53%. However, this is still substantially less than the voltage efficiency of about 80% observed in other ICLs, which had smooth carrier transport, suggesting room for further improvement. The extracted EQE under CW operation reached about 592% at 80 K, indicating the cascaded emission of photons in the ICL, and dropped to about 78% at 123 K as shown in FIG. 12A. Under pulsed operation, this device lased up to 155 K near 11.2 μm (FIG. 13) with a Jₜₕ of 196 A/cm², where the voltage efficiency dropped to 49% with a Vₜₕ of 4.52 V. The extracted EQE under pulsed operation reached about 640% at 80 K, subsequently dropping to 137% at 150 K, as shown in FIG. 13. The difference in the EQE at 80 K between CW and pulsed modes is attributed to heating in the active region of the device. The heating effect increased with the higher threshold current when the heat-sink temperature was raised, which was reflected by the greater decrease of the EQE in CW operation compared to that in pulsed operation, as shown in FIGS. 12A, 12B, and 13.

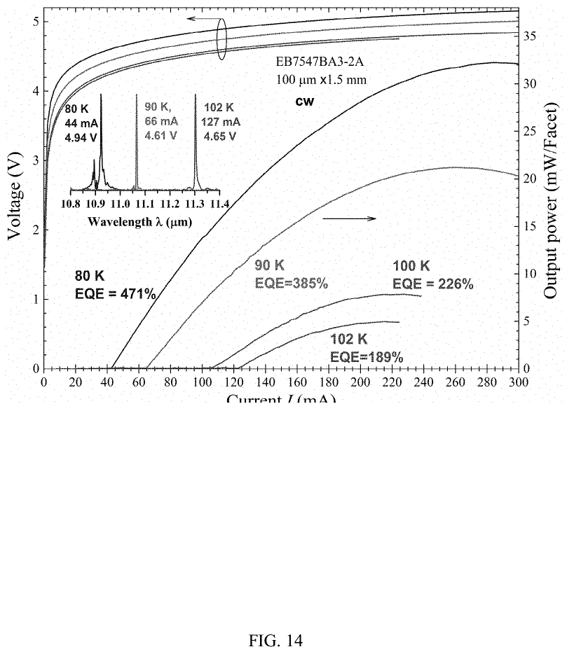

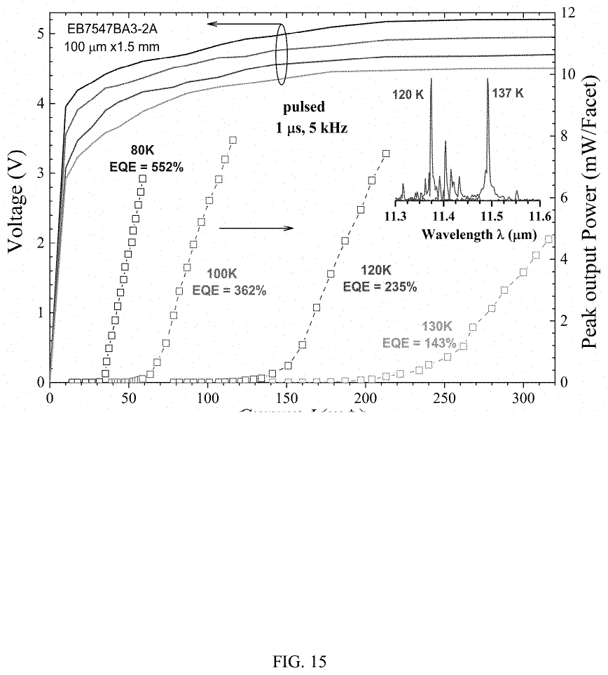

Compared to ICLs from EB7541, devices from wafer EB7547 lased at longer wavelengths as expected due to the slightly wider InAs QWs, and they had higher Jₜₕ and somewhat degraded temperature performance as shown in FIG. 11. In CW mode, a representative device, EB7547BA3-2A, lased at 10.9 μm at 80 K, with a Jₜₕ of 26.7 A/cm² and a Vₜₕ of 4.9 V. This ICL delivered output power of 32 mW/facet as shown in FIG. 14, higher than any interband laser has achieved at such a long wavelength. EB7547BA3-2A lased up to 102 K in CW mode at 11.3 μm with an EQE of 189% (FIG. 14), still exceeding the conventional limit of unity and indicating the potential for higher temperature operation. This device lased up to 137 K in pulsed mode at a Jₜₕ of 325 A/cm² and with a lasing wavelength of 11.5 μm as shown in FIG. 15, which is the longest among ICLs with the regular W-QWs. The extracted EQE in pulsed mode at 80 K for this device was 552%, which is comparable to that of EB7541BA3-3H.

Considering both wafers had the same waveguide, doping concentrations, and nearly identical active region designs, the small difference in the InAs QW width only resulted in an approximately 6.9% shift of lasing wavelength at 80 K. Hence, similar band structure, differential gain, and transparency current density would be expected for both. Consequently, they should have comparable threshold current density. This is also due to the fact that the free-carrier absorption loss difference between them is less than 20% based on the simulation shown in Table 1, which is supported by the comparable EQEs observed for them at 80 K, as shown in FIGS. 13 and 15. However, the Jₜₕ at 80 K in devices from EB7547 are about twice that compared to devices from EB7541, very different from the above perspectives and the observed insensitivity of the Jₜₕ at low temperatures (e.g., 80K) on the lasing wavelength for early ICLs. This suggests that extra factors beyond free carrier loss played a role in determining the Jₜₕ for devices from EB7547, which can be a subject of future research. In addition to the higher Jₜₕ, another issue in EB7547BA3-2A is that the EQE decreased relatively fast with the increase of temperature as shown in FIG. 15. Nevertheless, despite the higher Jₜₕ, its maximum operating temperature was only 18 K lower in pulsed mode than that of EB7541BA3-3H, since it could lase with a higher Jₜₕ than EB7541BA3-3H (325 A/cm² vs 196 A/cm²). Compared to a previous ICL, though improvements have been made, the maximum allowable Jₜₕ in devices from both wafers is still relatively small in contrast to other ICLs. This limited their maximum operating temperature in CW and pulsed modes.

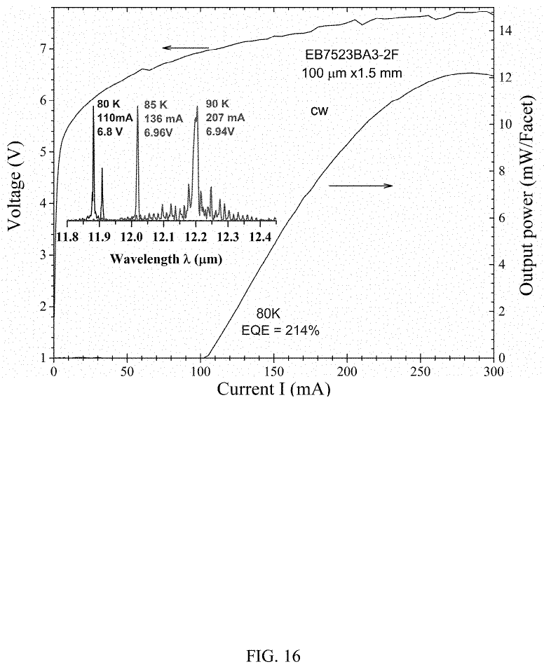

Wafers EB7523 and EB7539 both included the advanced waveguide as well as the InA_{0.5}P_{0.5} barriers in the QW active region. Multiple devices from both wafers lased in both CW and pulsed modes. A representative device EB7523BA3-2F lased in CW mode up to 90 K, with an emission wavelength of 12.2 μm and a Jth of about 138 A/cm² as shown in FIG. 16. This is a significant milestone as it is the first demonstration of a BA ICL operating in CW mode beyond 12 μm. Furthermore, the maximum obtainable output power at 80 K was 12 mW/facet (FIG. 16), which is comparable to and even higher than that of previous ICLs (without InA_{0.5}P_{0.5} barriers) at shorter wavelengths (10.8 and 10.2 μm). At 80 K, the Vₜₕ was about 6.8 V, corresponding to a voltage efficiency of about 31%. This low voltage efficiency indicates that there are likely issues in the carrier transport for ICLs containing InA_{0.5}P_{0.5} barriers. The extracted EQE at 80 K in CW mode reached 214%, as shown in FIG. 16 and validated the cascade process in ICLs with InAsP barriers for the first time.

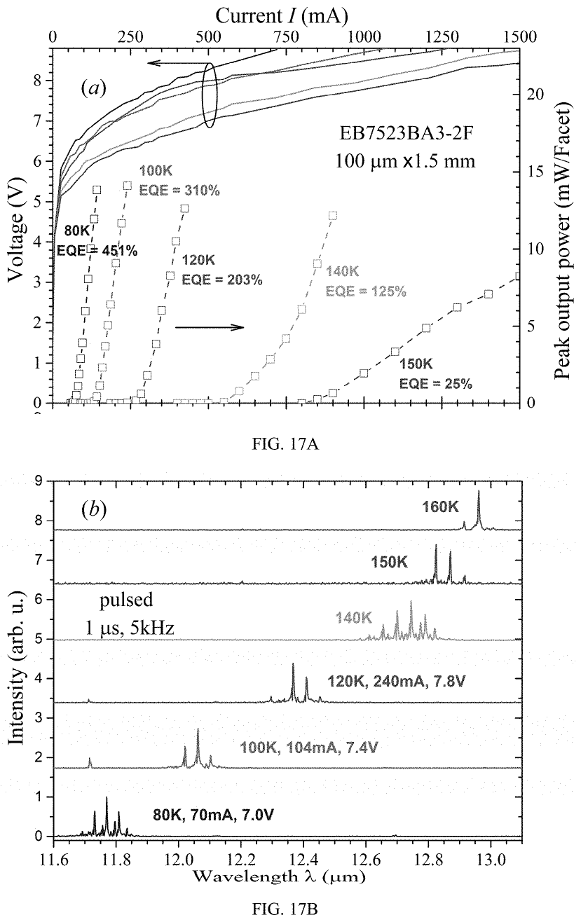

In pulsed mode, this device lased at 80 K at 11.8 μm, with a Jₜₕ of about 44 A/cm², which was reduced by a factor of nearly 4 compared to the previous ICL, while its EQE reached 451% at 80 K (FIGS. 17A and 17B), which is much higher than that (41%) in the initial ICL containing InA_{0.5}P_{0.5} barriers from wafer 7342. Additionally, this device operated in pulsed mode up to 160 K at 12.97 μm with a Jₜₕ of about 1267 A/cm², an increase of 40 K compared to the previous ICL from wafer 7342. Although this ICL lased at longer wavelengths near 13 μm, the operating temperature (160 K) of this device was even higher than the maximum pulsed operating temperature of ICLs at shorter wavelengths from wafers EB7541 and EB7547. These significant improvements suggest further potential of ICLs containing InA_{0.5}P_{0.5} barriers.

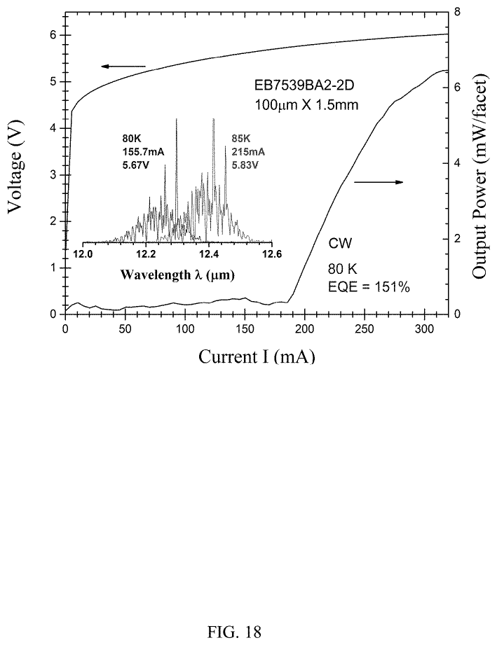

A representative 100 μm-wide device from wafer EB7539 also operated in CW mode up to 85 K with a Jₜₕ of about 143 A/cm² and at a lasing wavelength of 12.4 μm (FIG. 18), longer than devices from EB7523 and consistent with the design. It delivered an output power of 6.4 mW/facet at 80 K with a Vth of about 5.7 V, which corresponds to a voltage efficiency of about 35%, similar to devices from EB7523.

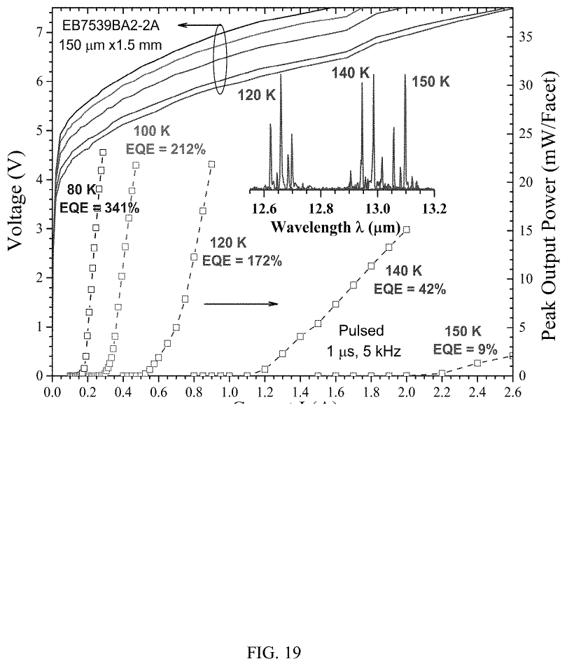

In pulsed operation, a 150 μm-wide device (EB7539BA2-2A) lased at 80 K with a Jₜₕ of about 64 A/cm², which is reduced about three times compared to the previous ICL from wafer 7342 with InAsP layers, and 45% higher than that of EB7523BA3-2F. Furthermore, this device lased in pulsed mode up to 150 K at 13.1 μm with a Jₜₕ of about 1111 A/cm². The extracted EQE in pulsed mode was about 341% at 80 K before dropping to about 9% at 150 K as shown in FIG. 19. Both EB7523 and EB7539 were able to hold significantly more current density at their maximum operating temperature compared with EB7541 and EB7547. Also, their differences in EQE and threshold current density are seemingly more mutually consistent in quantitative scale with their difference in the estimated free-carrier absorption loss shown in Table 1, in contrast to the differences between EB7541 and EB7547.

Compared to wafers 7289 and 7342, modifications in the latter 4 wafers to the waveguide, including layer thickness changes and doping concentration adjustments, resulted in enhanced device performance in the 10-13 μm wavelength region. Furthermore, the ICLs that included the active layer design change exhibited CW operation beyond 12 μm, which is the first demonstration of BA ICLs operating in CW mode at such long wavelengths. Several ICLs with this P-containing barrier have been explored with varying InAs and InA_{0.5}P_{0.5} layer thicknesses, which have helped to pave the way for better understanding of the expected lasing wavelength for this new kind of ICL. For practical applications, these long-wavelength ICLs need to be capable of operating near room temperature, or at least at temperatures accessible by thermoelectric cooling. With additional adjustments such ICLs should be able to achieve better performance in the 10-13 μm range at elevated temperatures.

While several embodiments have been provided in the present disclosure, it may be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, components, techniques, or methods without departing from the scope of the present disclosure. Other items shown or discussed as coupled may be directly coupled or may be indirectly coupled or communicating through some interface, device, or intermediate component whether electrically, mechanically, or otherwise. Other examples of changes, substitutions, and alterations are ascertainable by one skilled in the art and may be made without departing from the spirit and scope disclosed herein.

What is claimed is:

1. An interband cascade laser (ICL) comprising:
a plurality of interband cascade (IC) stages, wherein each of the IC stages comprises:
a hole injector;
an electron injector;
an active region coupled to the hole injector and the electron injector and comprising a first layer, wherein the first layer comprises a first material, and wherein the first material comprises indium arsenic phosphide (InAsP) or aluminum indium arsenic phosphide (AlInAsP);
a conduction band running through the hole injector, the electron injector, and the active region; and
a valence band running through the hole injector, the electron injector, and the active region.

2. The ICL of claim 1, wherein the active region further comprises a second layer, wherein the second layer comprise a second material, and wherein the second material comprises gallium indium antimonide (GaInSb).

3. The ICL of claim 2, wherein the active region further comprises two third layers coupled to and positioned adjacent to sides of the second layer, wherein one of the two third layers is adjacent to the first layer, wherein the third layers comprise a third material, and wherein the third material comprises indium arsenide (InAs).

4. The ICL of claim 3, wherein the active region further comprises a fourth layer, wherein the fourth layer comprises a fourth material, and wherein the fourth material comprises aluminum antimonide (AlSb) or aluminum antimony arsenide (AlSbAs).

5. The ICL of claim 4, wherein the first layer is about 16 angstroms (Å) thick, wherein the second layer is about 28 Å thick, wherein one of the two third layers that is closer to the electron injector is about 26.5 Å, wherein another of the two third layers that is closer to the hole injector is about 21.5 Å thick, and wherein the fourth layer is about 19 Å thick.

6. The ICL of claim 3, wherein the active region further comprises an additional first layer so that the third layers are positioned between the first layer and the additional first layer.

7. The ICL of claim 2, wherein the active region further comprises third layers coupled to and positioned adjacent to sides of the second layer, wherein the third layers comprise a third material, and wherein the third material comprises indium (In), arsenic (As), and nitrogen (N).

8. The ICL of claim 7, wherein the third material further comprises gallium (Ga).

9. The ICL of claim 2, wherein the InAsP is InAs_{0.5}P_{0.5}, and wherein the GalnSb is Ga_{0.65}In_{0.35}Sb.

10. An interband cascade laser (ICL) comprising:
a plurality of interband cascade (IC) stages, wherein each of the IC stages comprises:
a hole injector;
an electron injector;
an active region coupled to the hole injector and the electron injector and comprising a first layer, wherein the first layer comprises a first material, and wherein the first material comprises aluminum gallium indium arsenic phosphide (AlGaInAsP);
a conduction band running through the hole injector, the electron injector, and the active region; and
a valence band running through the hole injector, the electron injector, and the active region.

11. The ICL of claim 10, wherein the active region further comprises a second layer, wherein the second layer comprises a second material, and wherein the second material comprises gallium indium antimonide (GaInSb).

12. The ICL of claim 11, wherein the active region further comprises two third layers coupled to and positioned adjacent to sides of the second layer, wherein one of the two third layers is adjacent to the first layer, wherein the third layers comprise a third material, and wherein the third material comprises gallium indium arsenic nitride (GaInAsN).

13. The ICL of claim 12, wherein the active region further comprises a fourth layer, wherein the fourth layer comprises a fourth material, and wherein the fourth material comprises aluminum antimonide (AlSb) or aluminum antimony arsenide (AlSbAs).

14. The ICL of claim 13, wherein the first layer is about 7-16 angstroms (Å) thick, the second layer is about 21-35 Å thick, the third layers are about 20-30 Å thick, and the fourth layer is about 6-20 Å thick.

15. The ICL of claim 12, wherein the active region further comprises an additional first layer so that the third layers are positioned between the first layer and the additional first layer.

16. An interband cascade laser (ICL) comprising:
a plurality of interband cascade (IC) stages, wherein each of the IC stages comprises:
a hole injector;
an electron injector;
an active region coupled to the hole injector and the electron injector and comprising a first layer, wherein the first layer comprises a first material, and wherein the first material comprises aluminum gallium indium arsenic nitride (AlGaInAsN);
a conduction band running through the hole injector, the electron injector, and the active region; and
a valence band running through the hole injector, the electron injector, and the active region.

17. The ICL of claim 16, wherein the active region further comprises a second layer, wherein the second layer comprises a second material, and wherein the second material comprises gallium indium antimonide (GaInSb).

18. The ICL of claim 17, wherein the active region further comprises two third layers coupled to and positioned adjacent to sides of the second layer, wherein one of the two third layers is adjacent to the first layer, wherein the third layers comprise a third material, and wherein the third material comprises gallium indium arsenic nitride (GaInAsN).

19. The ICL of claim 18, wherein the active region further comprises a fourth layer, wherein the fourth layer comprises a fourth material, and wherein the fourth material comprises aluminum antimonide (AlSb) or aluminum antimony arsenide (AlSbAs).

20. The ICL of claim 18, wherein the active region further comprises an additional first layer so that the third layers are positioned between the first layer and the additional first layer.
